(19) United States
(12) Patent Application Publication
(10) Pub. No.: US 2025/0393450 A1
(43) Pub. Date: Dec. 25, 2025

(54) DISPLAY PANEL AND DISPLAY APPARATUS

(71) Applicants: BEIJING BOE TECHNOLOGY DEVELOPMENT CO., LTD., Beijing (CN); BOE Technology Group Co., Ltd., Beijing (CN)

(72) Inventors: Xu Li, Beijing (CN); Mingli Liu, Beijing (CN); Cheng Han, Beijing (CN); Qixiao Wu, Beijing (CN); Yanming Wang, Beijing (CN); Zhihui Zhang, Beijing (CN); Yansong Li, Beijing (CN)

(73) Assignees: BEIJING BOE TECHNOLOGY DEVELOPMENT CO., LTD., Beijing (CN); BOE Technology Group Co., Ltd., Beijing (CN)

(21) Appl. No.: 18/992,450

(22) PCT Filed: Apr. 18, 2024
(86) PCT No.: PCT/CN2024/088667

§ 371 Date: Jan. 8, 2025

(30) Foreign Application Priority Data
May 31, 2023 (CN) 202310640382.3

(51) Int. Cl. H10K 59/80; H10K 50/115; H10K 59/122; H10K 59/35

(52) U.S. Cl. CPC H10K 59/8792; H10K 50/115; H10K 59/122; H10K 59/35; H10K 59/873

(57) ABSTRACT

A display panel and a display apparatus are provided by the embodiments of the present application. The display panel includes: a first display region, a second display region and a black light absorbing layer. The first display region and the second display region are arranged at intervals. The first display region includes a plurality of first pixel units, and each of the plurality of first pixel units includes a red subpixel unit, a green subpixel unit and a blue subpixel unit. The second display region includes second pixel units, and each of the second pixel units includes blue subpixel units. In this way, under the premise of implementing the anti-peeping function, the resolution ratio and display effect of the display panel may not be affected in a normal display state because of satisfying the anti-peeping state.

### CROSS-REFERENCES TO RELATED APPLICATIONS

The present application claims the priority of the Chinese patent application filed on May 31, 2023 before the China National Intellectual Property Administration with the application number of 202310640382.3 and the title of “DISPLAY PANEL AND DISPLAY APPARATUS”, which is incorporated herein in its entirety by reference.

### TECHNICAL FIELD

The present disclosure relates to the technical field of display devices and, more particularly, to a display panel and a display apparatus.

### BACKGROUND

With continuous development of a display apparatus, the display performance of the display apparatus devices is increasingly evolving towards a more user-friendly direction. In order to meet needs of users for privacy protection, a display screen of the display apparatus typically has an anti-peeping function. That is, the display panel of the display apparatus experiences brightness decay at large viewing angles (greater than 30°) to achieve the anti-peeping effect.

Currently, in order to achieve the anti-peeping effect of the display panel, it is common to configure the display panel with first pixels and second pixels. The first pixels are smaller in size compared to the second pixels, and there is an optical blocking layer disposed above the first pixels that can block light from a large viewing angle. The brightness of the light emitted by the first pixels rapidly decays with the viewing angle to achieve the anti-peeping effect. In the anti-peeping state, only the first pixels are lightened, while in the conventional display state, the second pixels are lightened.

However, because only the second pixels are lightened in the conventional display state, a lower resolution ratio of the display panel in the conventional display state is caused to reduce the display effect of the display panel.

### SUMMARY

A display panel and a display apparatus are provided by embodiments of the present application to solve the problem that a resolution ratio of the display panel in the conventional display state caused by the implementation of the anti-peeping function is low in related art.

In order to solve the technical problem stated above, the present application is implemented as follows:

In a first aspect, a display panel is provided by the embodiments of the present application, wherein the display panel includes:
a first display region and a second display region, wherein the first display region and the second display region are arranged at intervals, a luminescent device of the first display region is a strong microcavity electroluminescence device;
the first display region includes a plurality of first pixel units, the second display region includes second pixel units, each of the plurality of first pixel units includes a red subpixel unit, a green subpixel unit and a blue subpixel unit; and each of the second pixel units includes blue subpixel units;
a black light absorbing layer, wherein the black light absorbing layer is disposed on a light-exiting surface of the first display region and a light-exiting surface of the second display region; an opening of the black light absorbing layer disposed on the light-exiting surface of the second display region is filled with a photo-excitation quantum dot material layer; and
when the display panel is in a first display state, the first display region and the second display region are in a lighting state, and when the display panel is in a second display state, the first display region is in a lighting state.

Optionally, the each of the second pixel units includes a first blue subpixel unit, a second blue subpixel unit and a third blue subpixel unit;
wherein the first blue subpixel unit emits red light under an action of the photo-excitation quantum dot material layer, and the second blue subpixel unit emits green light under an action of the photo-excitation quantum dot material layer.

Optionally, the photo-excitation quantum dot material layer includes a first material layer and a second material layer;
the first material layer is filled in a first opening area of the black light absorbing layer disposed on the light-exiting surface of the second display region, and the second material layer is filled in a second opening area of the black light absorbing layer disposed on the light-exiting surface of the second display region; and
an orthographic projection of the first opening area in a first direction overlaps with an orthographic projection of the first blue subpixel unit in the first direction, and an orthographic projection of the second opening area in the first direction overlaps with an orthographic projection of the second blue subpixel unit in the first direction, wherein the first direction is a direction perpendicular to a plane where the black light absorbing layer is located.

Optionally, a third opening area of the black light absorbing layer disposed on the light-exiting surface of the second display region is filled with scattering particles; and
an orthographic projection of the third opening area in the first direction overlaps with an orthographic projection of the third blue subpixel unit in the first direction.

Optionally, a ratio of a quantity of the first blue subpixel unit, a quantity of the second blue subpixel unit and a quantity of the third blue subpixel unit is 1:1:1.

Optionally, a size of the photo-excitation quantum dot material layer in a first direction is equal to a size of the black light absorbing layer disposed on the light-exiting surface of the second display region in the first direction, and the first direction is a direction perpendicular to a plane where the black light absorbing layer is located.

Optionally, a luminescent device of the second display region is a photoluminescence device or an electroluminescence device, and when the luminescent device of the second display region is the electroluminescence device, a size of the first display region in the first direction is less than a size of the second display region in the first direction.

Optionally, a quantity of the second pixel units is equal to a quantity of the plurality of first pixel units.

Optionally, a luminescent device of the blue subpixel unit included by the each of the plurality of first pixel units is a first luminescent device, and a luminescent device of each of the blue subpixel units included by the each of the second pixel units is a second luminescent device.

Optionally, a spectral peak of the first luminescent device is equal to a spectral peak of the second luminescent device.

Optionally, a spectral peak of the first luminescent device is less than a spectral peak of the second luminescent device, and the spectral peak of the second luminescent device is less than 500 nm.

Optionally, a sum of a quantity of the blue subpixel units included by the plurality of first pixel units and a quantity of the blue subpixel units included by the second pixel units is a first value, and the first value is equal to two-thirds of a total number of subpixel units included by the display panel.

Optionally, the display panel further includes a substrate;
a shape of an orthographic projection of the blue subpixel unit included by the each of the plurality of first pixel units on the substrate is a first pattern, and a shape of an orthographic projection of the blue subpixel unit included by the each of the second pixel units on the substrate is a second pattern.

Optionally, the first pattern and the second pattern are the same.

Optionally, the blue subpixel unit included by the each of the plurality of the first pixel units and the blue subpixel unit included by the each of the second pixel units are two different independent subpixel units.

Optionally, the display panel further includes a first luminescent layer, a second luminescent layer, a first pixel definition layer, a second pixel definition layer and a packaging layer;
the first pixel definition layer and the second pixel definition layer are disposed on the substrate, the first pixel definition layer includes a plurality of first opening areas, and the second pixel definition layer includes a plurality of second opening areas;
the first luminescent layer includes the red subpixel unit, the green subpixel unit and the blue subpixel unit included by multiple first pixel units arranged in the plurality of first opening areas; the second luminescent layer includes the blue subpixel units included by the second pixel units arranged in the second opening areas; and
the packaging layer is disposed on the first luminescent layer, the second luminescent layer, the first pixel definition layer and the second pixel definition layer, and the black light absorbing layer is disposed on the packaging layer.

Optionally, the display panel further includes a touch layer;
wherein the touch layer is arranged between the packaging layer and the black light absorbing layer.

Optionally, the packaging layer includes a first inorganic packaging layer, a second inorganic packaging layer and an organic packaging layer, the organic packaging layer is disposed between the first inorganic packaging layer and the second inorganic packaging layer; and
the first inorganic packaging layer is adhered to the first luminescent layer, the second luminescent layer, the first pixel definition layer and the second pixel definition layer.

In a second aspect, a display apparatus is further provided by the embodiments of the present application, wherein the display apparatus includes the display panel according to any one of embodiments in the first aspect.

It can be seen from the embodiments stated above, since the display panel includes a first display region, a second display region and a black light absorbing layer, the first display region includes a plurality of first pixel units, the second display region includes second pixel units, each of the plurality of first pixel units includes a red subpixel unit, a green subpixel unit and a blue subpixel unit; and each of the second pixel units includes blue subpixel units; the black light absorbing layer is disposed on a light-exiting surface of the first display region and a light-exiting surface of the second display region; an opening of the black light absorbing layer disposed on the light-exiting surface of the second display region is filled with a photo-excitation quantum dot material layer. Therefore, the display status of the display panel can be changed by changing the lighting status of the first display region and the lighting status of the second display region.

When the display panel is in a first display state, that is, the display panel is displaying normally (not in the anti-peeping display state), both the first display region and the second display region are in a lighting state, which means that the first pixel units included by the first display region and the second pixel units included by the second display region are lightened. In this way, since the opening of the black light absorbing layer disposed on the light-exiting surface of the second display region is filled with a photo-excitation quantum dot material layer, and the second pixel unit includes blue subpixel units, by using the photo-excitation quantum dot material layer, the light emitted by the blue subpixel units included by the second pixel unit can be excited to generate the color displayed by the red subpixel unit and the color displayed by the green subpixel unit. That is, in the normal display state, the resolution ratio of the display panel is equal to the sum of the resolution ratio of the first display region and the resolution ratio of the second display region, which is equivalent to that all pixel units included by the display panel can display. Additionally, since the opening of the black light absorbing layer disposed on the light-exiting surface of the second display region is filled with the photo-excitation quantum dot material layer, the second pixel unit can excite the photo-excitation quantum dot material layer to emit light. At large viewing angles (greater than 30°), the light-emitting portion of the second pixel unit is the photo-excitation quantum dot material layer, a relative position (a distance between the light-emitting portion of the second pixel unit and the substrate) of the light-emitting portion of the second pixel unit is higher than a relative position (a distance between the light-emitting portion of the first pixel unit and the substrate) of the light-emitting portion (the red subpixel unit, the green subpixel unit and the blue subpixel unit included by the first pixel unit) of the first pixel unit. Therefore, the second display region is not affected by the black light absorbing layer, resulting in that a resolution ratio of the display panel is higher, the image quality display effect of the display panel is better and brightness decay is slower.

When the display panel is in a second display state, that is, when the display panel is in the anti-peeping display state, the first display region is in a lighting state, that is, the first pixel unit included by the first display region emits light, while the second pixel unit included by the second display region does not emit light. In this way, at large viewing angles (greater than 30°), the light emitted by the first display region may be absorbed by the black light absorbing layer, and under the action of the strong microcavity of the first display region, the brightness of the display panel may significantly decay, thereby the anti-peeping effect is achieved.

In summary, by using the display panel provided by the embodiments of the present application, under the premise of realizing the anti-peeping function, in the normal display state (non-anti-peeping display state), the resolution ratio and display effect of the display panel may not be affected because of satisfying the anti-peeping state, which is beneficial for improving the display effect of the display panel.

### BRIEF DESCRIPTION OF THE DRAWINGS

In order to explain embodiments of the present application or the technical scheme in the related art more clearly, the drawings required to be used in the description of the embodiments or the related art may be briefly introduced below; obviously, the drawings in the following description are some embodiments of the present disclosure, and other drawings can be obtained according to these drawings by a person skilled in the art without paying creative labor.

FIG. 1 shows a schematic diagram of a structure of a display panel according to an embodiment of the present disclosure;

FIG. 2 shows a schematic diagram of pixel distribution of a display panel according to an embodiment of the present disclosure;

FIG. 3 shows a schematic diagram of a cross-section structure at an A-A position of a first display region included by a display panel in FIG. 1 according to an embodiment of the present disclosure;

FIG. 4 shows a schematic diagram of a cross-section structure at a B-B position of a first display region included by a display panel in FIG. 1 according to an embodiment of the present disclosure;

FIG. 5 shows a first schematic diagram of brightness decay simulation of a display panel according to an embodiment of the present disclosure; and

FIG. 6 shows a second schematic diagram of brightness decay simulation of a display panel according to an embodiment of the present disclosure

### REFERENCE NUMERALS

1: first display region; 2: second display region; 3: black light absorbing layer; 4: photo-excitation quantum dot material layer; 5: first luminescent layer; 6: second luminescent layer; 7: first pixel definition layer; 8: second pixel definition layer; 9: packaging layer; 10: touch layer; 11: first pixel unit; 21: second pixel unit; 41: first material layer; 42: second material layer; 91: first inorganic packaging layer; 92: second inorganic packaging layer; 93: organic packaging layer; 211: first blue subpixel unit; 212: second blue subpixel unit; and 213: third blue subpixel unit.

### DETAILED DESCRIPTION

The technical solutions according to the embodiments of the present disclosure will be clearly and completely described below with reference to the drawings according to the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

It should be understood that the “one embodiment” or “an embodiment” as used throughout the specification means that particular features, structures or characteristics with respect to the embodiments are included by at least one embodiment of the present disclosure. Therefore, the “in one embodiment” or “in an embodiment” as used throughout the specification does not necessarily refer to the same embodiment. Furthermore, these particular features, structures or characteristics may be combined in one or more embodiments in any suitable form.

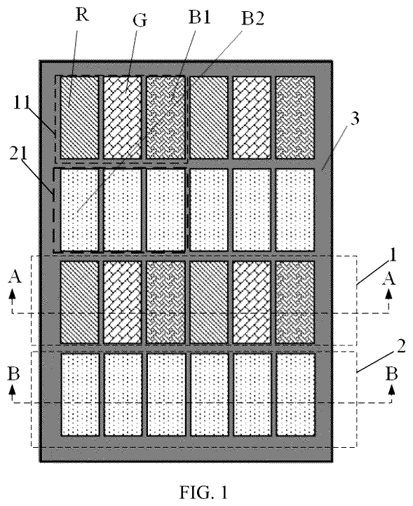

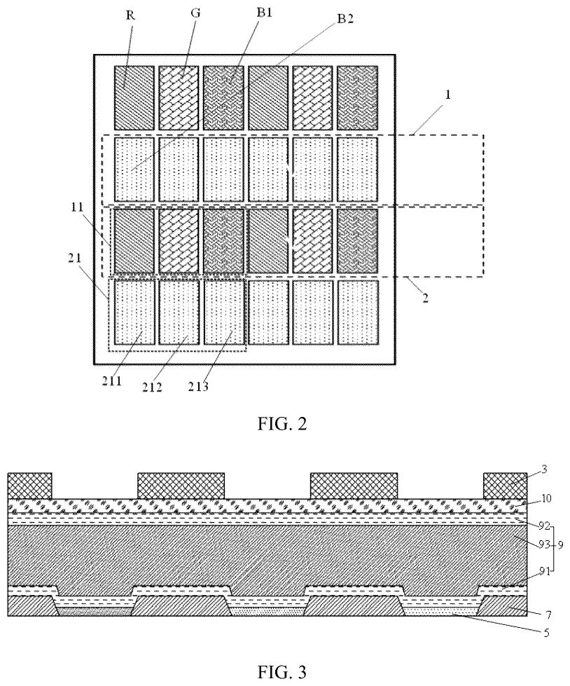

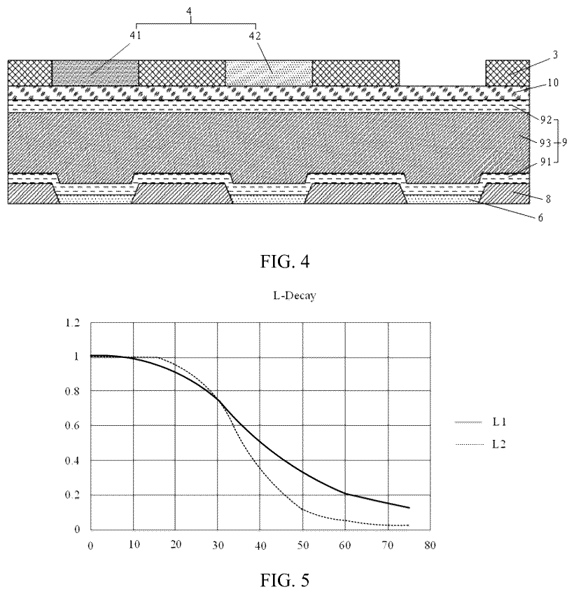

In a first aspect, a display panel is provided by embodiments of the present application. FIG. 1 shows a schematic diagram of a structure of a display panel according to an embodiment of the present disclosure. FIG. 2 shows a schematic diagram of pixel distribution of a display panel according to an embodiment of the present disclosure. FIG. 3 shows a schematic diagram of a cross-section structure at an A-A position of a first display region included by a display panel in FIG. 1 according to an embodiment of the present disclosure. FIG. 4 shows a schematic diagram of a cross-section structure at a B-B position of a first display region included by a display panel in FIG. 1 according to an embodiment of the present disclosure. As shown in FIGS. 1, 2, 3 and 4, the display panel includes a first display region 1, a second display region 2 and a black light absorbing layer 3, wherein the first display region 1 and the second display region 2 are arranged at intervals, a luminescent device of the first display region 1 is a strong microcavity electroluminescence device. The first display region 1 includes a plurality of first pixel units 11, the second display region 2 includes second pixel units 21, each of the plurality of first pixel units 11 includes a red subpixel unit, a green subpixel unit and a blue subpixel unit; and each of the second pixel units 21 includes blue subpixel units. The black light absorbing layer 3 is disposed on a light-exiting surface of the first display region 1 and a light-exiting surface of the second display region 2. An opening of the black light absorbing layer 3 disposed on the light-exiting surface of the second display region 2 is filled with a photo-excitation quantum dot material layer 4.

When the display panel is in a first display state, the first display region 1 and the second display region 2 are in a lighting state, and when the display panel is in a second display state, the first display region 1 is in a lighting state.

The first display region 1 and the second display region 2 are arranged in sequence, that is, the first display region 1 and the second display region 2 are distributed in an alternating manner. At least one second display region 2 is located between two adjacent first display regions 1, and at least one first display region 1 is located between two adjacent second display regions 2. The luminescent device of the first display region 1 and the luminescent device of the second display region 2 may be the same, or the luminescent device of the first display region 1 and the luminescent device of the second display region 2 may also be different, which is not limited by the embodiments of the present application. Regardless of whether the luminescent device of the first display region 1 is the same as the luminescent device of the second display region 2 or the luminescent device of the first display region 1 is different from the luminescent device of the second display region 2, the first display region 1 is a strong microcavity electroluminescence device. It should be noted that “microcavity” refers to the state or structure where light is repeatedly reflected between a reflective electrode and a semi-reflective semi-transparent electrode, and is enhanced through constructive interference. In related art, in order to utilize a microcavity structure, a plurality of reflective electrodes with different step heights for each pixel can be formed in a plurality of anode electrodes.

It should also be noted that, as shown in FIG. 5, the horizontal coordinate represents the angle of viewing angle, while the vertical coordinate represents brightness decay. From FIG. 5, it can be seen that brightness decays rapidly as the viewing angle increases. Exemplarily, according to European standard vehicle specifications, the current European specification is that: when the viewing angle is less than or equal to 10°, the brightness decay of the device is greater than or equal to 90% (i.e., brightness decay does not exceed 10%). When the viewing angle is greater than 40°, the brightness decay of the device is less than 5% (i.e., brightness decay exceeds 95%), the anti-peeping view angle is entered. As shown in FIG. 5, L1 represents that the overall brightness decay of the strong microcavity device complies with European standard specification for the viewing angle less than or equal to 30°. Although the brightness decay accelerates for the viewing angle greater than 30°, the European standard specification cannot still be met. Comparing with conventional electroluminescence devices (a weak microcavity device represented by L2 in FIG. 5), the brightness decay of the strong microcavity device tends to 20% for large viewing angles (greater than 30°), while the brightness decay for small viewing angles (less than or equal to 30°) shows a certain degree of slowing down, providing a basis for the anti-peeping of the display panel. In summary, since the first display region 1 is a strong microcavity electroluminescence device, the brightness decay of the first display region 1 for the large viewing angles (greater than 30°) may tend to 20%, thereby the first display region 1 may be enabled to be in an anti-peeping state.

In addition, in the embodiments of the present application, a pixel unit refers to the basic unit that constitutes the basic primary pigment and grayscale of a display panel. Each pixel unit includes a red subpixel, a green subpixel and a blue subpixel. The first display region 1 includes a plurality of first pixel units 11, each first pixel unit 11 includes a red subpixel unit, a green subpixel unit and a blue subpixel unit. The red subpixel unit included by the first pixel unit 11 is represented as R in FIG. 1, the green subpixel unit included by the first pixel unit 11 is represented as G in FIG. 1, and the blue subpixel unit included by the first pixel unit 11 is represented as B1 in FIG. 1. A proportion of the red subpixel unit in the first pixel unit 11, a proportion of the green subpixel unit in the first pixel unit 11 and a proportion of the blue subpixel unit in the first pixel unit 11 can be set in a ratio of 1:1:1, or it can be set in other ratios. The proportion of the red subpixel unit in the first pixel unit 11, the proportion of the green subpixel unit in the first pixel unit 11 and the proportion of the blue subpixel unit in the first pixel unit 11 are determined based on the display requirements of the display panel, which is not limited by the embodiments of the present application. Furthermore, a pixel shape of the red subpixel unit, a pixel shape of the green subpixel unit and a pixel shape of the blue subpixel unit can be any one of shapes such as strip, square, circle, etc. Additionally, the shape of the red subpixel unit, the shape of the green subpixel unit and the shape of the blue subpixel unit can be the same or different, which is not limited by the embodiments of the present application.

The blue subpixel unit included by the second pixel unit 21 can be the same as or different from the blue subpixel unit included by the first pixel unit 11, that is, the shape of the blue subpixel units included by the second pixel unit 21 can be the same as or different from the shape of the blue subpixel unit included by the first pixel unit 11. The blue subpixel unit included by the second pixel unit 21 is represented as B2 in FIG. 1. A quantity of the blue subpixel units included by the second pixel unit 21 is the same as a quantity of the blue subpixel units included by the first pixel unit 11, both the quantity of the blue subpixel unit included by the second pixel unit 21 and the quantity of the blue subpixel unit included by the first pixel unit Ilare three. The shapes of the three blue subpixel units included by the second pixel unit 21 can be the same or different. It should be noted that among the three primary color subpixel units of the red subpixel unit, the green subpixel unit and the blue subpixel unit, the blue subpixel unit is the native self-emitting component of the display panel. Therefore, the red subpixel unit and the green subpixel unit can be excited by using the blue subpixel unit through quantum dots, thus full-color display on the display panel is achieved. Based on this, in the embodiments of the present application, the second pixel unit included by the second display region includes only the blue subpixel units, thereby providing the conditions for the subsequent generation of the blue subpixel unit from the native blue subpixel unit, as well as the generation of the red subpixel unit and the green subpixel unit excited by different quantum dots from the blue subpixel unit.

In addition, both the light-exiting surface of the first display region 1 and the light-exiting surface of the second display region 2 are provided with a black light absorbing layer 3, that is, the black light absorbing layer 3 covers the display region of the display panel, thus by using the black light absorbing layer 3, light emitted at a large viewing angle (greater than 30°) from the first display region 1 and light emitted at a large viewing angle (greater than 30°) from the second display region 2 are absorbed. Furthermore, the blue subpixel unit may be generated form the native blue subpixel unit included by the second pixel unit, and the red subpixel unit and the green subpixel unit may be generated by exciting different quantum dots from the blue subpixel unit included by the second pixel unit, thus the opening of the black light absorbing layer 3 disposed on the light-exiting surface of the second display region 2 can be filled with a photo-excitation quantum dot material layer 4 to make the light emitted by the blue subpixel unit included by the second pixel unit be excited to generate different colors through the photo-excitation quantum dot material layer 4. It should be noted that the opening of the black light absorbing layer 3 refers to the opening area on the black light absorbing layer 3 that is used for emitting light, that is, the orthographic projection of the opening of the black light absorbing layer 3 on the substrate completely overlaps with the orthographic projection of the blue subpixel unit included by the second pixel unit on the substrate.

From the above embodiments, it can be seen that in the embodiments of the present application, since the display panel includes the first display region 1 and the second display region 2, the first display region 1 includes a plurality of first pixel units 11, and the second display region 2 includes the second pixel units 21, each of the plurality of first pixel units 11 includes a red subpixel unit, a green subpixel unit and a blue subpixel unit; and each of the second pixel units 21 includes blue subpixel units; the black light absorbing layer 3 is disposed on a light-exiting surface of the first display region 1 and a light-exiting surface of the second display region 2; an opening of the black light absorbing layer 3 disposed on the light-exiting surface of the second display region 2 is filled with a photo-excitation quantum dot material layer 4. Therefore, the display status of the display panel can be changed by changing the lighting status of the first display region 1 and the lighting status of the second display region 2.

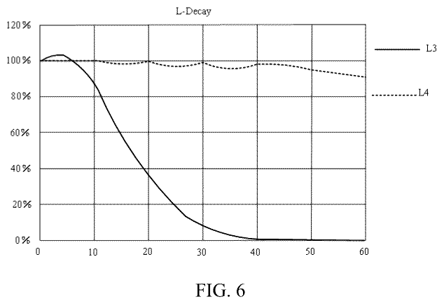

When the display panel is in the first display state, that is, the display panel is displaying normally (not in the anti-peeping display state), both the first display region 1 and the second display region 2 are in a lighting state, which means that the first pixel units 11 included by the first display region 1 and the second pixel units 21 included by the second display region 2 are lightened. In this way, since the opening of the black light absorbing layer 3 disposed on the light-exiting surface of the second display region 2 is filled with a photo-excitation quantum dot material layer 4, and the second pixel unit 21 includes blue subpixel units, by using the photo-excitation quantum dot material layer 4, the light emitted by the blue subpixel units included by the second pixel unit can be excited to generate the color displayed by the red subpixel unit and the color displayed by the green subpixel unit. That is, in the normal display state, the resolution ratio of the display panel is equal to the sum of the resolution ratio of the first display region 1 and the resolution ratio of the second display region 2, which is equivalent to that all pixel units included by the display panel can display. Additionally, since the opening of the black light absorbing layer 3 disposed on the light-exiting surface of the second display region 2 is filled with the photo-excitation quantum dot material layer 4, the second pixel unit 21 can excite the photo-excitation quantum dot material layer 4 to emit light. As shown by L4 in FIG. 6, at large viewing angles (greater than 30°), the light-emitting portion of the second pixel unit 21 is the photo-excitation quantum dot material layer 4, a relative position (a distance between the light-emitting portion of the second pixel unit 21 and the substrate) of the light-emitting portion of the second pixel unit 21 is higher than a relative position (a distance between the light-emitting portion of the first pixel unit 11 and the substrate) of the light-emitting portion (the red subpixel unit, the green subpixel unit and the blue subpixel unit included by the first pixel unit 11) of the first pixel unit 11. Therefore, the second display region 2 is not affected by the black light absorbing layer 3, resulting in that a resolution ratio of the display panel is higher, the image quality display effect of the display panel is better and brightness decay is slower.

When the display panel is in a second display state, that is, when the display panel is in the anti-peeping display state, the first display region 1 is in a lighting state, that is, the first pixel unit 11 included by the first display region 1 emits light, while the second pixel unit 21 included by the second display region 2 does not emit light. In this way, as shown by L3 in FIG. 6, at large viewing angles (greater than 30°), the light emitted by the first display region 1 may be absorbed by the black light absorbing layer 3, and under the action of the strong microcavity of the first display region 1, the brightness of the display panel may be significantly decayed, thereby the anti-peeping effect is achieved.

In summary, by using the display panel provided by the embodiments of the present application, under the premise of realizing the anti-peeping function, in the normal display state (non-anti-peeping display state), the resolution ratio and display effect of the display panel may not be affected because of satisfying the anti-peeping state, which is beneficial for improving the display effect of the display panel.

Next, the structure of the first pixel unit 11 in the first display region 1 and the structure of the second pixel unit 21 in the second display region 2 are specifically described as follows:

In some embodiments, as shown in FIG. 2, each second pixel unit 21 includes a first blue subpixel unit 211, a second blue subpixel unit 212 and a third blue subpixel unit 213. The first blue subpixel unit 211 emits red light under an action of the photo-excitation quantum dot material layer 4, and the second blue subpixel unit 212 emits green light under an action of the photo-excitation quantum dot material layer 4.

It should be noted that the photo-excitation quantum dot material layer 4 refers to that the energy levels of quantum dots in a semiconductor material change when they are excited by light. Electrons transition from the valence band to the conduction band, and energy is released during the transitioning process. These energies excite the luminescent centers in the material to generate light emission phenomenon. Based on this, since among the three primary color subpixel units of the red subpixel unit, the green subpixel unit and the blue subpixel unit, the blue subpixel unit is the native self-emitting component of the display panel, the red subpixel unit and the green subpixel unit can be excited through the quantum dots by using the blue subpixel unit, thus full-color display on the display panel is achieved. Therefore, in the embodiments of the present application, the first blue subpixel unit 211 emits red light under the action of the photo-excitation quantum dot material layer 4, and the second blue subpixel unit 212 emits green light under the action of the photo-excitation quantum dot material layer 4. In this way, combined with the blue light emitted by the native third blue subpixel unit 213, the second display region 2 may have a full-color display condition.

Furthermore, the photo-excitation quantum dot material layer 4 includes a first material layer 41 and a second material layer 42. The first material layer 41 is filled in a first opening area of the black light absorbing layer 3 disposed on the light-exiting surface of the second display region, and the second material layer 42 is filled in a second opening area of the black light absorbing layer 3 disposed on the light-exiting surface of the second display region 2; an orthographic projection of the first opening area in a first direction overlaps with an orthographic projection of the first blue subpixel unit 211 in the first direction, and an orthographic projection of the second opening area in the first direction overlaps with an orthographic projection of the second blue subpixel unit 212 in the first direction, wherein the first direction is a direction perpendicular to a plane where the black light absorbing layer 3 is located.

It should be noted that the first material layer 41 is a photo-excitation quantum dot material layer emitting red light, while the second material layer 42 is a photo-excitation quantum dot material layer emitting green light. In this way, the first opening area of the black light absorbing layer 3 disposed on the light-exiting surface of the second display region is filled with the first material layer 41, and the second opening area of the black light absorbing layer 3 disposed on the light-exiting surface of the second display region is filled with the second material layer 42. Since the orthographic projection of the first opening area in a first direction overlaps with the orthographic projection of the first blue subpixel unit 211 in the first direction, and the orthographic projection of the second opening area in the first direction overlaps with the orthographic projection of the second blue subpixel unit 212 in the first direction, the first blue subpixel can be excited to emit red light under the action of the first material layer 41, and the second blue subpixel can be excited to emit green light under the action of the second material layer 42, thereby the second display region 2 may have a full-color display condition. At the same time, under the action of the first material layer 41, when the display panel is in the anti-peeping state, the brightness decay degree of the light emitted by the first blue subpixel is consistent with the decay degree of the red subpixel unit in the first display region 1. Under the action of the second material layer 42, when the display panel is in the anti-peeping state, the brightness decay degree of the light emitted by the second blue subpixel is consistent with the decay degree of the green subpixel unit in the first display region 1, at the same time, the anti-peeping requirements of the display panel are met.

Furthermore, a third opening area of the black light absorbing layer 3 disposed on the light-exiting surface of the second display region is filled with scattering particles; and an orthographic projection of the third opening area in the first direction overlaps with an orthographic projection of the third blue subpixel unit 213 in the first direction.

It should be noted that since the third blue subpixel unit 213 only needs to emit its own blue light and does not need to be excited to generate the light with other colors, the third opening area of the black light absorbing layer 3 disposed on the light-exiting surface of the second display region is filled with scattering particles. Additionally, because the orthographic projection of the third opening area in the first direction overlaps with the orthographic projection of the third blue subpixel unit 213 in the first direction, the scattering particles are set by filing the scattering particles in the third opening area of the black light absorbing layer 3, when the display panel is in the anti-peeping state, the brightness decay degree of the light emitted by the third blue subpixel is consistent with the decay degree of the blue subpixel unit in the first display region 1.

Optionally, a ratio of a quantity of the first blue subpixel unit 211, a quantity of the second blue subpixel unit 212 and a quantity of the third blue subpixel unit 213 is 1:1:1. In this way, the display effect (red, green, and blue primary colors) of the subpixel units included by the second pixel unit 21 can be ensured to be consistent with the display effect of the red subpixel unit, the green subpixel unit and the blue subpixel unit included by the first pixel unit 11, which is beneficial for ensuring the display effect of the display panel.

Regarding the size requirements for the photo-excitation quantum dot material layer 4, in some embodiments, the size of the photo-excitation quantum dot material layer 4 in the first direction is equal to the size of the black light absorbing layer 3 disposed on the light-exiting surface of the second display region 2 in the first direction. The first direction is a direction perpendicular to a plane where the black light absorbing layer is located.

It should be noted that since the size of the photo-excitation quantum dot material layer 4 in the first direction is equal to the size of the black light absorbing layer 3 disposed on the light-exiting surface of the second display region 2 in the first direction, that the photo-excitation quantum dot material layer 4 and the black light absorbing layer 3 are positioned within the same layer can be ensured. In this way, the black light absorbing layer 3 can be prevented from blocking the light emission of the photo-excitation quantum dot material layer 4 to ensure the display effect of the display panel in normal display state.

Furthermore, under the premise that the size of the photo-excitation quantum dot material layer 4 in the first direction is equal to the size of the black light absorbing layer 3 disposed on the light-exiting surface of the second display region 2 in the first direction, a luminescent device of the second display region 2 is a photoluminescence device or an electroluminescence device, and when the luminescent device of the second display region 2 is the electroluminescence device, a size of the first display region 1 in the first direction is less than a size of the second display region 2 in the first direction.

It should be noted that when the luminescent device of the second display region 2 is an electroluminescence device, it is necessary to set up a circuit that controls both the second pixel unit 21 and the photo-excitation quantum dot material layer 4 to be lightened simultaneously. Therefore, the circuit is arranged at the bottom of the second pixel unit 21. Based on this, in order to avoid the black light absorbing layer 3 from blocking the photo-excitation quantum dot material layer 4 due to the arrangement of the circuit, the size of the photo-excitation quantum dot material layer 4 in the first direction needs to be equal to the size of the black light absorbing layer 3 disposed on the light-exiting surface of the second display region 2 in the first direction, that is, the bottom of the photo-excitation quantum dot material layer 4 is raised. It should also be noted that when the luminescent device in the second display region 2 is an electroluminescence device, it needs to be ensured that the size of the first display region 1 in the first direction is less than the size of the second display region 2 in the first direction, thus the black light absorbing layer on the first display region 1 and the black light absorbing layer on the second display region 2 are positioned within the same plane to avoid any impact on the light emission effect of the photo-excitation quantum dot material layer 4 due to the circuit arrangement.

Regarding the quantity of the second pixel unit 21 and the quantity of the first pixel unit 11, in the embodiments of the present application, the quantity of the second pixel unit 21 is equal to the quantity of the first pixel unit 11. That is to say, the proportion of the first display region 1 occupied on the display surface of the display panel is equal to the proportion of the second display region 2 occupied on the display surface of the display panel, so that the quantity of the second pixel unit 21 accounts for one half of the total number of the pixel units of the display panel. In this way, when the display panel is switched between the normal display state (non-anti-peeping state) and the anti-peeping state, the anti-peeping effect of the display panel can be guaranteed in the anti-peeping state, and the display effect of the display panel can be ensured when the display panel is in the normal display state.

Optionally, a luminescent device of the blue subpixel unit included by the each of the plurality of first pixel units 11 is a first luminescent device, and a luminescent device of each of the blue subpixel units included by the each of the second pixel units 21 is a second luminescent device.

It should be noted that a spectral peak of the first luminescent device and a spectral peak of the second luminescent device can be equal, that is, the luminescent device of the blue subpixel unit included by the first pixel unit 11 and the luminescent device of the blue subpixel unit included by the second pixel unit 21 can be the same luminescent device. Alternatively, the spectral peak of the first luminescent device and the spectral peak of the second luminescent device can be unequal, that is, the luminescent device of the blue subpixel unit included by the first pixel unit 11 and the luminescent device of the blue subpixel unit included by the second pixel unit 21 can be different luminescent devices, thereby the luminescent device of the blue subpixel unit included by the second pixel unit 21 is independently designed.

Furthermore, in a possible embodiment, the spectral peak of the first luminescent device is equal to the spectral peak of the second luminescent device. In the present embodiment, the luminescent device of the blue subpixel unit included by the first pixel unit 11 and the luminescent device of the blue subpixel unit included by the second pixel unit 21 can be the same luminescent device, thus the first pixel units 11 of the first display region 1 and the second pixel units 21 of the second display region 2 can be formed by using the same evaporation method, which is beneficial for reducing manufacturing costs.

Further, in another possible embodiment, the spectral peak of the first luminescent device is less than the spectral peak of the second luminescent device, and the spectral peak of the second luminescent device is less than 500 nm. In the present embodiment, the luminescent device of the blue subpixel unit included by the second pixel unit 21 can be independently designed, facilitating adjustments to the type of luminescent device of the blue subpixel unit included by the second pixel unit 21 based on the display effect of the second display region 2 to meet different display requirements.

In some embodiments, when the intensity of the microcavity of the first pixel unit 11 decreases, the size of the black light absorbing layer 3 in the first direction increases, wherein the first direction is the direction perpendicular to the plane where the black light absorbing layer is located.

It should be noted that due to the decrease in the intensity of the microcavity of the first pixel unit 11, the brightness decay of the first display region 1 is reduced. In this case, it is necessary to increase the size of the black light absorbing layer 3 in the first direction, that is, the thickness of the black light absorbing layer 3 is increased. Meanwhile, the photo-excitation quantum dot material layer 4 disposed at the opening of the black light absorbing layer 3 of the second display region 2 moves upward with the black light absorbing layer 3. The increase in the thickness of the black light absorbing layer 3 compensates for the reduced brightness decay degree of the first display region 1, ensuring the anti-peeping effect of the display panel while avoiding blocking the photo-excitation quantum dot material layer 4 caused by the increased thickness of the black light absorbing layer 3.

Regarding the requirement for the quantity of the blue subpixel units, in some embodiments, a sum of a quantity of the blue subpixel units included by the plurality of first pixel units 11 and a quantity of the blue subpixel units included by the second pixel units 21 is a first value, and the first value is equal to two-thirds of a total number of subpixel units included by the display panel. In this way, when the display panel is switched between the normal display state (non-anti-peeping state) and the anti-peeping state, the anti-peeping effect of the display panel can be guaranteed in the anti-peeping state, and the display effect of the display panel can be ensured when the display panel is in the normal display state.

For the shapes of the subpixel units included by the first pixel unit 11 and the shapes of the subpixel units included by the second pixel unit 21, the display panel further includes a substrate; a shape of an orthographic projection of the blue subpixel unit included by the each of the plurality of first pixel units 11 on the substrate is a first pattern, and a shape of an orthographic projection of the blue subpixel unit included by the each of the second pixel units 21 on the substrate is a second pattern.

Optionally, in a possible embodiment, the first pattern and the second pattern are the same. In the present embodiment, since the first pattern and the second pattern are the same, the first pixel unit 11 and the second pixel unit 21 can be formed by using the same evaporation process, which is beneficial for saving the manufacturing costs of the display panel.

Optionally, in another possible embodiment, the blue subpixel unit included by the first pixel unit 11 and the blue subpixel unit included by the second pixel unit 21 are two different independent subpixel units, that is, the shape of the orthographic projection of the blue subpixel unit included by the first pixel unit 11 on the substrate is the shape of the first pattern, and the shape of the orthographic projection of the blue subpixel unit included by the second pixel unit 21 on the substrate is the shape of the second pattern, the shape of the orthographic projection of the blue subpixel unit included by the first pixel unit 11 on the substrate is different from the shape of the orthographic projection of the blue subpixel unit included by the second pixel unit 21 on the substrate. In the present embodiment, since the blue subpixel unit included by the first pixel unit 11 and the blue subpixel unit included by the second pixel unit 21 are two different independent subpixel units, the blue subpixel unit included by the second pixel unit 21 can be designed independently, facilitating adjustments to the shape of the blue subpixel unit included by the second pixel unit 21 based on the display effect of the second display region 2 to meet different display requirements.

Regarding the specific structure of the display panel, as shown in FIGS. 2 and 4, in some embodiments, the display panel further includes a first luminescent layer 5, a second luminescent layer 6, a first pixel definition layer 7, a second pixel definition layer 8 and a packaging layer 9; the first pixel definition layer 7 and the second pixel definition layer 8 are disposed on the substrate, the first pixel definition layer 7 includes a plurality of first opening areas, and the second pixel definition layer 8 includes a plurality of second opening areas; the first luminescent layer 5 includes the red subpixel unit, the green subpixel unit and the blue subpixel unit included by multiple first pixel units 11 arranged in the plurality of first opening areas; the second luminescent layer 6 includes the blue subpixel units included by the second pixel units 21 arranged in the second opening areas; and the packaging layer 9 is disposed on the first luminescent layer 5, the second luminescent layer 6, the first pixel definition layer and the second pixel definition layer, and the black light absorbing layer 3 is disposed on the packaging layer 9.

It should be noted that since the first luminescent layer 5 includes the red subpixel units, the green subpixel units and the blue subpixel units included by the first pixel units 11 arranged in the first opening areas, and the second luminescent layer 6 includes the blue subpixel units included by the second pixel units 21 arranged in the second opening areas, the light emitted by the first luminescent layer 5 may be enabled to achieve an anti-peeping effect under the action of the black light absorbing layer 3. The second luminescent layer 6 excites the photo-excitation quantum dot material layer 4 to achieve an anti-peeping effect. In a normal display state, both the first luminescent layer 5 and the second luminescent layer 6 can be lightened simultaneously, thereby that the resolution ratio of the display panel is not reduced due to the anti-peeping arrangement is ensured.

Optionally, the display panel further includes a touch layer 10; wherein the touch layer 10 is arranged between the packaging layer 9 and the black light absorbing layer 3. In this way, while the display panel has touch functionality, the anti-peeping effect of the black light absorbing layer 3 may not be affected due to the touch layer 10.

Optionally, the packaging layer 9 may include a first inorganic packaging layer 91, a second inorganic packaging layer 92 and an organic packaging layer 93, the organic packaging layer 93 is disposed between the first inorganic packaging layer 91 and the second inorganic packaging layer 92; and the first inorganic packaging layer 91 is adhered to the first luminescent layer 5, the second luminescent layer 6, the first pixel definition layer 7 and the second pixel definition layer 8. The second inorganic packaging layer 92 is disposed between the black light absorbing layer 3 and the organic packaging layer 92. In this way, the organic packaging layer 93 on the first pixel definition layer 7 and the second pixel definition layer 8 restricts the first inorganic packaging layer 91 to the area defined by the organic packaging layer 93, overflow of inorganic materials used in the production of the first inorganic packaging layer 91 can be avoided, and the organic packaging layer 93 plays a role in blocking.

From the above embodiments, it can be seen that in the embodiments of the present application, since the display panel includes the first display region 1 and the second display region 2, the first display region 1 includes a plurality of first pixel units 11, and the second display region 2 includes the second pixel units 21, each of the plurality of first pixel units 11 includes a red subpixel unit, a green subpixel unit and a blue subpixel unit; and each of the second pixel units 21 includes blue subpixel units; the black light absorbing layer 3 is disposed on a light-exiting surface of the first display region 1 and a light-exiting surface of the second display region 2; an opening of the black light absorbing layer 3 disposed on the light-exiting surface of the second display region 2 is filled with a photo-excitation quantum dot material layer 4. Therefore, the display status of the display panel can be changed by changing the lighting status of the first display region 1 and the lighting status of the second display region 2.

When the display panel is in the first display state, that is, the display panel is displaying normally (not in the anti-peeping display state), both the first display region 1 and the second display region 2 are in a lighting state, which means that the first pixel units 11 included by the first display region 1 and the second pixel units 21 included by the second display region 2 are lightened. In this way, since the opening of the black light absorbing layer 3 disposed on the light-exiting surface of the second display region 2 is filled with a photo-excitation quantum dot material layer 4, and the second pixel unit 21 includes blue subpixel units, by using the photo-excitation quantum dot material layer 4, the light emitted by the blue subpixel units included by the second pixel unit can be excited to generate the color displayed by the red subpixel unit and the color displayed by the green subpixel unit. That is, in the normal display state, the resolution ratio of the display panel is equal to the sum of the resolution ratio of the first display region 1 and the resolution ratio of the second display region 2, which is equivalent to that all pixel units included by the display panel can display. Additionally, since the opening of the black light absorbing layer 3 disposed on the light-exiting surface of the second display region 2 is filled with the photo-excitation quantum dot material layer 4, the second pixel unit 21 can excite the photo-excitation quantum dot material layer 4 to emit light. As shown by L4 in FIG. 6, at large viewing angles (greater than 30°), the light-emitting portion of the second pixel unit 21 is the photo-excitation quantum dot material layer 4, a relative position (a distance between the light-emitting portion of the second pixel unit 21 and the substrate) of the light-emitting portion of the second pixel unit 21 is higher than a relative position (a distance between the light-emitting portion of the first pixel unit 11 and the substrate) of the light-emitting portion (the red subpixel unit, the green subpixel unit and the blue subpixel unit included by the first pixel unit 11) of the first pixel unit 11. Therefore, the second display region 2 is not affected by the black light absorbing layer 3, resulting in that a resolution ratio of the display panel is higher, the image quality display effect of the display panel is better and brightness decay is slower.

When the display panel is in a second display state, that is, when the display panel is in the anti-peeping display state, the first display region 1 is in a lighting state, that is, the first pixel unit 11 included by the first display region 1 emits light, while the second pixel unit 21 included by the second display region 2 does not emit light. In this way, as shown by L3 in FIG. 6, at large viewing angles (greater than 30°), the light emitted by the first display region 1 may be absorbed by the black light absorbing layer 3, and under the action of the strong microcavity of the first display region 1, the brightness of the display panel may be significantly decayed, thereby the anti-peeping effect is achieved.

In summary, by using the display panel provided by the embodiments of the present application, under the premise of realizing the anti-peeping function, in the normal display state (non-anti-peeping display state), the resolution ratio and display effect of the display panel may not be affected because of satisfying the anti-peeping state, which is beneficial for improving the display effect of the display panel.

In a second aspect, a display apparatus is further provided by the embodiments of the present application, the display apparatus includes functional devices and the display panel according to any one of the above embodiments.

It should be noted that the display apparatus can be mobile display apparatuses such as mobile phones, tablet computers, laptops, handheld computers, vehicle-mounted display apparatus, wearable devices, ultra-mobile personal computers (UMPCs), netbooks, or personal digital assistants (PDAs). Non-mobile display devices may be personal computers (PCs), televisions (TVs), teller machines or self-service machines and so on, which is not limited by the embodiments of the present application. The beneficial effects of the display apparatus are consistent with beneficial effects of the display panel stated above, which is not repeated by the embodiments of the present application.

It should be noted that the embodiments in the specification are described in the mode of progression, each of the embodiments emphatically describes the differences from the other embodiments, and the same or similar parts of the embodiments may be referred to each other.

Although alternative embodiments of the embodiments of the present disclosure have been described, once a person skilled in the art has known the essential inventive concept, he may make further variations and modifications on those embodiments. Therefore, the appended claims are intended to be interpreted as including the alternative embodiments and all of the variations and modifications that fall within the scope of the embodiments of the present disclosure.

Finally, it should also be noted that, herein, relation terms such as first and second are merely intended to distinguish one entity from another entity, and that does not necessarily require or imply that those entities have therebetween any such actual relation or order. Furthermore, the terms “include”, or any variants thereof are intended to cover non-exclusive inclusions, so that articles or terminal devices that include a series of elements do not only include those elements, but also include other elements that are not explicitly listed, or include the elements that are inherent to such articles or terminal devices. Unless further limitation is set forth, an element defined by the wording “including a . . . ” does not exclude additional same element in the article or terminal device including the element.

The technical solutions of the present disclosure have been described in detail above. The principle and the embodiments of the present disclosure are described herein with reference to the particular examples. Moreover, for a person skilled in the art, according to the principle and the implementations of the present disclosure, the particular embodiments and the range of application may be varied. In conclusion, the contents of the description should not be understood as limiting the present disclosure.

1. A display panel, wherein the display panel comprises:
a first display region and a second display region, wherein the first display region and the second display region are arranged at intervals, a luminescent device of the first display region is a strong microcavity electroluminescence device;
the first display region comprises a plurality of first pixel units, the second display region comprises second pixel units, each of the plurality of first pixel units comprises a red subpixel unit, a green subpixel unit and a blue subpixel unit; and each of the second pixel units comprises blue subpixel units;
a black light absorbing layer, wherein the black light absorbing layer is disposed on a light-exiting surface of the first display region and a light-exiting surface of the second display region; an opening of the black light absorbing layer disposed on the light-exiting surface of the second display region is filled with a photo-excitation quantum dot material layer; and
when the display panel is in a first display state, the first display region and the second display region are in a lighting state, and when the display panel is in a second display state, the first display region is in a lighting state.

2. The display panel according to claim 1, wherein the each of the second pixel units comprises a first blue subpixel unit, a second blue subpixel unit and a third blue subpixel unit;
wherein the first blue subpixel unit emits red light under an action of the photo-excitation quantum dot material layer, and the second blue subpixel unit emits green light under an action of the photo-excitation quantum dot material layer.

3. The display panel according to claim 2, wherein the photo-excitation quantum dot material layer comprises a first material layer and a second material layer;
the first material layer is filled in a first opening area of the black light absorbing layer disposed on the light-exiting surface of the second display region, and the second material layer is filled in a second opening area of the black light absorbing layer disposed on the light-exiting surface of the second display region; and
an orthographic projection of the first opening area in a first direction overlaps with an orthographic projection of the first blue subpixel unit in the first direction, and an orthographic projection of the second opening area in the first direction overlaps with an orthographic projection of the second blue subpixel unit in the first direction, wherein the first direction is a direction perpendicular to a plane where the black light absorbing layer is located.

4. The display panel according to claim 3, wherein a third opening area of the black light absorbing layer disposed on the light-exiting surface of the second display region is filled with scattering particles; and
an orthographic projection of the third opening area in the first direction overlaps with an orthographic projection of the third blue subpixel unit in the first direction.

5. The display panel according to claim 2, wherein a ratio of a quantity of the first blue subpixel unit, a quantity of the second blue subpixel unit and a quantity of the third blue subpixel unit is 1:1:1.

6. The display panel according to claim 1, wherein a size of the photo-excitation quantum dot material layer in a first direction is equal to a size of the black light absorbing layer disposed on the light-exiting surface of the second display region in the first direction, and the first direction is a direction perpendicular to a plane where the black light absorbing layer is located.

7. The display panel according to claim 6, wherein a luminescent device of the second display region is a photoluminescence device or an electroluminescence device, and when the luminescent device of the second display region is the electroluminescence device, a size of the first display region in the first direction is less than a size of the second display region in the first direction.

8. The display panel according to claim 1, wherein a quantity of the second pixel units is equal to a quantity of the plurality of first pixel units.

9. The display panel according to claim 1, wherein a luminescent device of the blue subpixel unit comprised by the each of the plurality of first pixel units is a first luminescent device, and a luminescent device of each of the blue subpixel units comprised by the each of the second pixel units is a second luminescent device.

10. The display panel according to claim 9, wherein a spectral peak of the first luminescent device is equal to a spectral peak of the second luminescent device.

11. The display panel according to claim 9, wherein a spectral peak of the first luminescent device is less than a spectral peak of the second luminescent device, and the spectral peak of the second luminescent device is less than 500 nm.

12. The display panel according to claim 1, wherein a sum of a quantity of the blue subpixel units comprised by the plurality of first pixel units and a quantity of the blue subpixel units comprised by the second pixel units is a first value, and the first value is equal to two-thirds of a total number of subpixel units comprised by the display panel.

13. The display panel according to claim 1, wherein the display panel further comprises a substrate;
a shape of an orthographic projection of the blue subpixel unit comprised by the each of the plurality of first pixel units on the substrate is a first pattern, and a shape of an orthographic projection of the blue subpixel unit comprised by the each of the second pixel units on the substrate is a second pattern.

14. The display panel according to claim 13, wherein the first pattern and the second pattern are the same.

15. The display panel according to claim 13, wherein the blue subpixel unit comprised by the each of the plurality of the first pixel units and the blue subpixel unit comprised by the each of the second pixel units are two different independent subpixel units.

16. The display panel according to claim 13, wherein the display panel further comprises a first luminescent layer, a second luminescent layer, a first pixel definition layer, a second pixel definition layer and a packaging layer;
the first pixel definition layer and the second pixel definition layer are disposed on the substrate, the first pixel definition layer comprises a plurality of first opening areas, and the second pixel definition layer comprises a plurality of second opening areas;
the first luminescent layer comprises the red subpixel unit, the green subpixel unit and the blue subpixel unit comprised by multiple first pixel units arranged in the plurality of first opening areas; the second luminescent layer comprises the blue subpixel units comprised by the second pixel units arranged in the second opening areas; and
the packaging layer is disposed on the first luminescent layer, the second luminescent layer, the first pixel definition layer and the second pixel definition layer, and the black light absorbing layer is disposed on the packaging layer.

17. The display panel according to claim 16, wherein the display panel further comprises a touch layer;
wherein the touch layer is arranged between the packaging layer and the black light absorbing layer.

18. The display panel according to claim 16, wherein the packaging layer comprises a first inorganic packaging layer, a second inorganic packaging layer and an organic packaging layer, the organic packaging layer is disposed between the first inorganic packaging layer and the second inorganic packaging layer; and
the first inorganic packaging layer is adhered to the first luminescent layer, the second luminescent layer, the first pixel definition layer and the second pixel definition layer.

19. A display apparatus, wherein the display apparatus comprises the display panel according to claim 1.

20. The display apparatus according to claim 19, wherein the each of the second pixel units comprises a first blue subpixel unit, a second blue subpixel unit and a third blue subpixel unit;
wherein the first blue subpixel unit emits red light under an action of the photo-excitation quantum dot material layer, and the second blue subpixel unit emits green light under an action of the photo-excitation quantum dot material layer.
